(19) United States
(12) Patent Application Publication
(10) Pub. No.: US 2024/0154057 A1
(43) Pub. Date: May 9, 2024

(54) LIGHT EMITTING DEVICE AND DISPLAY DEVICE INCLUDING THE SAME

(71) Applicant: LG Display Co., Ltd., Seoul (KR)

(72) Inventors: Il-Soo KIM, Goyang-si (KR); Hyowon KWON, Suwon-si (KR)

(73) Assignee: LG Display Co., Ltd., Seoul (KR)

(21) Appl. No.: 18/232,699

(22) Filed: Aug. 10, 2023

(30) Foreign Application Priority Data
Nov. 7, 2022 (KR) 10-2022-0146686

(51) Int. Cl. H01L 33/06; H01L 25/16; H01L 33/38

(52) U.S. Cl. CPC H01L 33/06; H01L 25/167; H01L 33/382

(57) ABSTRACT

A light-emitting device can include a semiconductor structure including a undoped semiconductor layer, a superlattice layer, a first semiconductor layer, a light-emitting layer, and a second semiconductor layer; a protective layer disposed on a side surface of the semiconductor structure; a first electrode electrically connected to the first semiconductor layer; and a second electrode electrically connected to the second semiconductor layer. Also, a recess is formed in the undoped semiconductor layer and the superlattice layer, and the recess exposes a portion of a surface of the first semiconductor layer.

### CROSS-REFERENCE TO RELATED APPLICATION

This application claims priority under 35 U.S.C. § 119 to Korean Patent Application No. 10-2022-0146686 filed on Nov. 7, 2022 in the Republic of Korea, the entirety of which is herein incorporated by reference.

### BACKGROUND

### Field

The present disclosure relates to a light-emitting device and a display device including the light-emitting device, and more particularly, to a light-emitting device with improved current injection efficiency, and a display device including the light-emitting device.

### Description of Related Art

A display device used for a computer monitor, TV, a mobile phone, etc. can include an organic light-emitting display device (OLED) that emits light by itself, and a liquid crystal display device (LCD) that requires a separate light source (e.g., a backlight unit).

Applications for display devices are diversifying from the computer monitor and TV to the personal portable device. Research is being conducted on a display device with a reduced volume and weight while having a large display area.

Further, recently, a display device including an LED (Light Emitting Diode) light-emitting element is attracting attention as a next-generation display device. Since the LED is made of an inorganic material rather than an organic material, the LED-based display device has excellent reliability and has a longer lifespan than that of each of the liquid crystal display device and the organic light-emitting display device. The LED not only lights up quickly, but also has excellent light-emitting efficiency, excellent stability due to strong impact resistance, and can display an image at high luminance. However, when the LEDs are made to be smaller and smaller, current may not be uniformly applied to the light emitting layer which can impair luminance (e.g., as the LED is made smaller, the current can begin to start concentrating at the sides of LED before reaching the light emitting layer, rather than being uniformly applied to the entire light emitting layer). Thus, there exists a need to be able to make very small LEDs while still being able to maintain high luminance. Also, there exists a need for very small LEDs that maintain high luminance that have a configuration that can improve manufacturing yields and decrease the occurrence of alignment defects or connection defects.

### SUMMARY OF THE DISCLOSURE

In order to use an LED as a light-emitting element and apply the LED to the display device, a very small LED with a size of several tens of μm is applied to the display device.

A purpose to be achieved by the present disclosure is to provide a light-emitting element in which a portion of a superlattice layer included in the light-emitting element is etched to improve injection efficiency of current passing through the light-emitting element, and a display device including the light-emitting element.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A light-emitting device according to one embodiment of the present disclosure for achieving the purpose as described above includes a semiconductor structure including a undoped semiconductor layer, a superlattice layer, a first semiconductor layer, a light-emitting layer, and a second semiconductor layer; a protective layer disposed on a side surface of the semiconductor structure; a first electrode electrically connected to the first semiconductor layer; and a second electrode electrically connected to the second semiconductor layer. In this regard, a recess is formed in the undoped semiconductor layer and the superlattice layer to expose a portion of a surface of the first semiconductor layer. Accordingly, the current injection efficiency of the light-emitting element can be improved.

A display device according to another embodiment of the present disclosure for achieving the purpose as described above includes a substrate; a first connection electrode and a second connection electrode disposed on the substrate; and a light-emitting element including a first electrode connected to the first connection electrode and a second electrode connected to the second connection electrode. In this regard, the light-emitting element includes: a undoped semiconductor layer including a first inner side surface and a first outer side surface; a superlattice layer disposed on the undoped semiconductor layer and including a second inner side surface and a second outer side surface; a first semiconductor layer disposed on the superlattice layer; a light-emitting layer disposed on the first semiconductor layer; and a second semiconductor layer disposed on the light-emitting layer. Accordingly, efficiency of the light-emitting element can be improved, and thus, power consumption of the display device can be reduced.

Details of the other embodiments are included in the detailed description and drawings.

According to the embodiments of the present disclosure, the portion of the superlattice layer included in the light-emitting element can be etched away, such that an amount of current leaking to the side surface of the light-emitting element can be reduced, and an amount of the current passing through the light-emitting layer can be increased.

According to the embodiments of the present disclosure, the electrode constituting the light-emitting element can be spaced apart from the superlattice layer and can directly contact the semiconductor layer, thereby reducing an amount of the current leaking to the side surface of the light-emitting element via the superlattice layer.

According to the embodiments of the present disclosure, in a light-emitting element having the recess, a height from a contact surface between the semiconductor layer and the electrode to an upper surface of the semiconductor layer can be smaller than a distance from the inner side surface of the undoped semiconductor layer to the outer side surface thereof. Thus, an amount of the current leakage to the side surface of the light-emitting element can be reduced, and thus, the internal quantum efficiency thereof can be increased.

Effects of the present disclosure are not limited to the effects mentioned above, and other effects not mentioned will be clearly understood by those skilled in the art from the descriptions below.

### BRIEF DESCRIPTION OF DRAWINGS

The above and other objects, features, and advantages of the present disclosure will become more apparent to those of ordinary skill in the art by describing example embodiments thereof in detail with reference to the attached drawings, which are briefly described below.

FIG. 1 is a schematic configuration diagram of a display device according to one embodiment of the present disclosure.

FIG. 2 is a schematic plan view of a display panel included in a display device according to one embodiment of the present disclosure.

FIG. 3 and FIG. 4 are schematic cross-sectional views of a light-emitting element according to one embodiment of the present disclosure.

FIG. 5 is a cross-sectional view of a light-emitting element implemented using a semiconductor structure as shown in FIG. 4 according to an embodiment of the present disclosure.

FIG. 6 is a cross-sectional view of a light-emitting element according to another embodiment of the present disclosure.

FIG. 7 is a cross-sectional view of a light-emitting element according to still another embodiment of the present disclosure.

FIG. 8A to FIG. 8E are diagrams of a method for manufacturing a light-emitting element according to one embodiment of the present disclosure.

FIG. 9 is a cross-sectional view of a display device according to one embodiment of the present disclosure.

FIG. 10 is a cross-sectional view of a display device according to another embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “including,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to,” or “electrically connected to” another element or layer, it can be directly on, connected to, or electrically connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event can occur therebetween unless “directly after,” “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first,” “second,” “third,” and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

It will be understood that when an element or layer is referred to as being “connected to,” or “electrically connected to” another element or layer, it can be directly on, connected to, or electrically connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term “or” means “inclusive or” rather than “exclusive or.” That is, unless otherwise stated or clear from the context, the expression that “x uses a or b” means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific situation, a term can be arbitrarily selected by the applicant, and in this situation, the detailed meaning thereof will be described in a corresponding description section. Therefore, the terms used in the description below should be understood based on not simply the name of the terms, but the meaning of the terms and the contents throughout the Detailed Descriptions.

Hereinafter, various embodiments of the present disclosure will be described in detail with reference to the accompanying drawings.

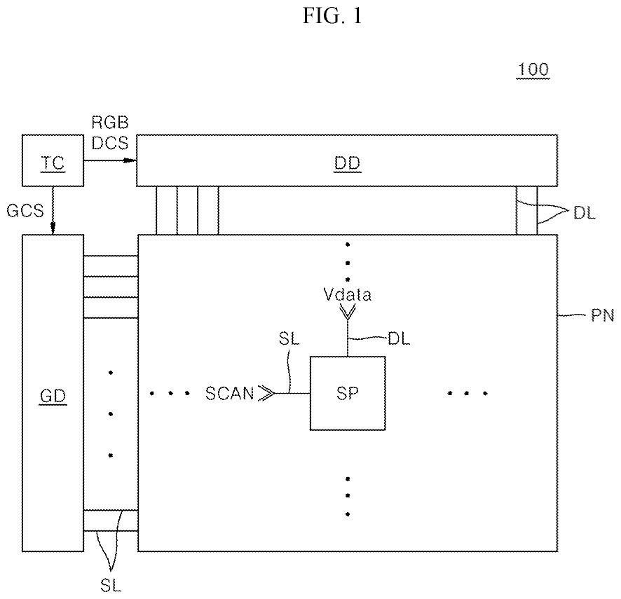

FIG. 1 is a schematic plan view of a display device according to one embodiment of the present disclosure.

Particularly, FIG. 1 shows a display panel PN, a gate driver GD, a data driver DD, and a timing controller TC among various components of a display device 100 for convenience of illustration.

Referring to FIG. 1, the display device 100 includes the display panel PN including a plurality of sub-pixels SP, the gate driver GD and the data driver DD that supply various signals to the display panel PN, and the timing controller TC that controls the gate driver GD and the data driver DD.

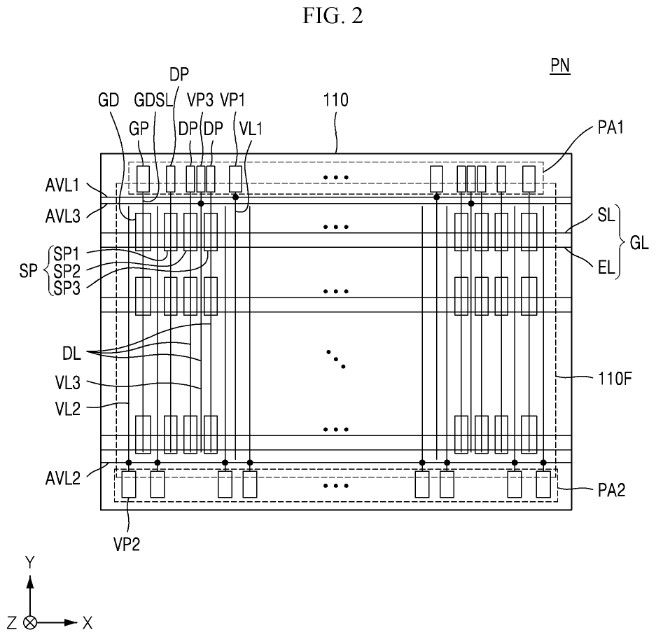

The display panel PN is a component for displaying an image to a user, and includes the plurality of sub-pixels SP. In the display panel PN, a plurality of scan lines SL and a plurality of data lines DL intersect each other, and each of the plurality of sub-pixels SP is connected to the scan line SL and the data line DL. Further, each of the plurality of sub-pixels SP can be connected to a high-potential voltage line VL1, a low-potential voltage line VL2, a reference voltage line VL3, and the like (e.g., see FIG. 2).

Each of the plurality of sub-pixels SP is a minimum unit constituting a screen, and each of the plurality of sub-pixels SP includes a light-emitting element and a pixel circuit for driving the light-emitting element. A type of each of a plurality of light-emitting elements can vary based on a type of the display panel PN. For example, when the display panel PN is embodied as an inorganic light-emitting display panel, the light-emitting element can be embodied as an LED (Light-emitting Diode) or a micro-LED (Micro Light-emitting Diode).

The gate driver GD respectively supplies a plurality of scan signals SCAN to the plurality of scan lines SL under a plurality of gate control signals GCS provided from the timing controller TC. FIG. 1 shows that one gate driver GD is disposed on one side of the display panel PN and is spaced apart therefrom. However, the number and arrangement of the gate driver GD is not limited thereto.

The data driver DD converts image data RGB input from the timing controller TC into a data voltage Vdata using a reference gamma voltage under a plurality of data control signals DCS provided from the timing controller TC. The data driver DD can supply the converted data voltage Vdata to each of the plurality of data lines DL.

The timing controller TC aligns video data RGB input from an external source and supplies the aligned video data RGB to the data driver DD. The timing controller TC can generate the gate control signal GCS and the data control signal DCS using synchronization signals input from an external device, for example, a dot clock signal, a data enable signal, and a horizontal/vertical synchronization signal. The timing controller TC can supply the generated gate control signal GCS and data control signal DCS to the gate driver GD and the data driver DD, respectively to control the gate driver GD and the data driver DD.

Hereinafter, the display panel PN of the display device 100 according to one embodiment of the present disclosure will be described in detail.

FIG. 2 is a schematic plan view of a display panel included in a display device according to one embodiment of the present disclosure. In FIG. 2, only a substrate 110, a plurality of pixels, pads, and lines among various components of the display device 100 are shown for convenience of illustration.

The substrate 110 is a component for supporting various components included in the display panel PN, and can be made of an insulating material. For example, the substrate 110 can be made of glass or resin. Further, the substrate 110 can be made of a polymer or plastic, and can be made of material with flexibility.

The substrate 110 can be divided into a display area and a non-display area. The display area is an area where a plurality of unit pixels are arranged and an image is displayed. One unit pixel can include at least two or more sub-pixels. In the figure, one unit pixel is illustrated to include three sub-pixels SP1, SP2, and SP3. However, the present disclosure is not limited thereto. The three sub-pixels include the first sub-pixel SP1, the second sub-pixel SP2, and the third sub-pixel SP3. In following descriptions, any one sub-pixel among the three sub-pixels is denoted by SP.

Each of the plurality of sub-pixels SP is an individual emitting light unit. A light-emitting element and a pixel circuit are disposed in each of the plurality of sub-pixels SP. A unit pixel including the three sub-pixels SP1, SP2, and SP3 can include a red sub-pixel, a green sub-pixel, and a blue sub-pixel, or can include at least two of a red sub-pixel, a green sub-pixel, a blue sub-pixel, and a white sub-pixel. However, the present disclosure is not limited thereto. A unit pixel can include at least two sub-pixels, each including a light-emitting element having the lowest light-emitting efficiency among a red light-emitting element, a green light-emitting element, and a blue light-emitting element.

The display device 100 according to one embodiment of the present disclosure includes the first sub-pixel SP1 emitting red light, the second sub-pixel SP2 emitting green light, and the third sub-pixel SP3 emitting blue light, in which the first sub-pixel SP1, the second sub-pixel SP2, and the third sub-pixel SP3 can be arranged side by side in the first direction. In this situation, the first direction refers to an X-axis direction.

As mentioned above, the display area is an area in which a plurality of unit pixels are disposed, and the non-display area is an area in which an image is not displayed and can be an area in which a plurality of unit pixels are not disposed. The non-display area can include an area where the gate driver GD for driving the plurality of sub-pixels SP arranged in the display area, lines, and a pad for applying a signal to the lines are disposed.

The gate driver GD supplies a gate signal to the plurality of sub-pixels SP via the gate line GL. The gate signal includes a scan signal and a light-emission signal. The scan signal is provided via the scan line SL, and the light-emission signal is provided via a light-emission line EL. The scan line SL and the light-emission line EL can be collectively referred to as the gate line GL.

The gate driver GD includes a scan driver that provides the scan signal and a light-emission driver that provides the light-emission signal.

In the display device 100 according to one embodiment of the present disclosure, the gate driver GD can include a plurality of gate drivers GD disposed on the substrate 110, and each of the plurality of gate drivers GD can be disposed between adjacent ones of the plurality of pixels.

The light-emitting element included in the display device 100 according to one embodiment of the present disclosure can be embodied as an LED (Light-emitting Diode) or an inorganic light-emitting element. Since the LED has excellent light-emitting efficiency, an area occupied by the LED in a sub-pixel SP area can be very small. Accordingly, the LED and the pixel circuit for driving the LED can be disposed in each sub-pixel SP. The gate driver GD can be disposed in a non-display area of at least one sub-pixel SP or at least one unit pixel.

Referring to FIG. 2, each gate driver GD can be disposed in each unit pixel and can provide the gate signal to the sub-pixels SP arranged in the same row (the X-axis) in which the gate driver GD and the sub-pixels SP are arranged. The arrangement structure of the gate drivers GD is not limited thereto, and an arrangement density of the gate drivers GD can be changed in some situations.

The scan driver and the light-emission driver included in the gate driver GD are arranged in the same row (X-axis). However, the scan driver and the light-emission driver included in the gate driver GD can be disposed in different areas.

The data driver DD converts the video data into the data signal and supplies the converted data signal to the sub-pixel SP via the data line DL. The data driver DD can be formed on a rear surface of the substrate 110 or on an auxiliary substrate. When the data driver DD is formed on one surface of a separate substrate, the other surface thereof on which the data driver DD is not formed can be bonded to a rear surface of the substrate 110 to face each other. To electrically connect the front and rear surfaces of the substrate 110 to each other or electrically connect the front surface of the substrate 110 and the other surface of the auxiliary substrate to each other, a side line is disposed on a side surface of the substrate 110 or the auxiliary substrate. Therefore, the data driver disposed on the rear surface of the substrate 110 or the other surface of the auxiliary substrate can supply the data signal to the sub-pixel SP via the side line.

As described above, in the display device 100 according to one embodiment of the present disclosure, the gate driver GD can be disposed on the substrate 110 and between adjacent unit pixels. However, the present disclosure is not limited thereto, and the gate driver GD may not include the plurality of gate drivers, each being disposed between adjacent unit pixels, but the gate driver GD can be disposed only on one side of the substrate 110 or only on each of both opposing sides thereof.

In one example, the gate line GL can extend in a row direction (X-axis direction) and can be disposed on the substrate 110, while the data line DL can be disposed on the substrate and can extend in a column direction (Y-axis direction). The gate line GL and the data line DL can be disposed in each of the sub-pixels SP to provide the signals to the pixel circuit disposed in each of the sub-pixels SP.

Pad areas PA1 and PA2 in which pads are disposed are respectively disposed on both opposing areas of the substrate 110, that is, to upper and lower areas of the substrate 110 arranged in the column direction (Y-axis direction). In this situation, the pad area disposed on the upper area of the substrate 110 can be referred to as the first pad area PA1, and the pad area disposed on the lower area of the substrate 110 can be referred to as the second pad area PA2. On the substrate 110, the first pad area PA1 and the second pad area PA2 are opposite to each other.

In the first pad area PA1, a data pad DP connected to the data line DL, a gate pad GP connected to the gate driver GD, a high-potential voltage pad VP1 connected to the high-potential voltage line VL1, and a reference voltage pad VP3 connected to the reference voltage line VL3 can be disposed. In this situation, the number of the data pads DP can correspond to the number of sub-pixels SP.

A line providing various clock signals, a line providing a gate low voltage, and a line providing a gate high voltage can disposed in the gate driver GD. The gate drivers GD can be arranged side by side in the column direction (Y-axis direction) so that the line transmitting the signal to the gate driver GD is aligned with the gate driver GD. The line that transmits the signal to the gate driver GD can be referred to as a gate driving line GDSL. The gate driving line GDSL can extend in a column direction (Y-axis direction) and can be connected to the gate pad GP disposed in the first pad area PA1, and can receive the signal from the gate pad GP.

The high-potential voltage line VL1 can extend in the column direction (Y-axis direction) and can be disposed in each unit pixel or each sub-pixel SP. In the drawing, it is illustrated that the high-potential voltage line VL1 is disposed in each unit pixel and is disposed on a left or right side of the unit pixel. However, the present disclosure is not limited thereto. The high-potential voltage line VL1 extending in the column direction (Y-axis direction) receives a high-potential voltage from the high-potential voltage pad VP1 disposed in the first pad area PA1 and provides the high-potential voltage to the plurality of sub-pixels SP. A plurality of high-potential voltage lines VL1 extending in the column direction (Y-axis direction) can be connected to and intersect auxiliary high-potential voltage lines AVL1 extending in the row direction (X-axis direction) to form a mesh structure. The auxiliary high-potential voltage line AVL1 can be disposed adjacent to the first pad area PA1. The auxiliary high-potential voltage line AVL1 can prevent a voltage drop of the high-potential voltage line VL1 and can provide the high-potential voltage to the plurality of sub-pixels SP.

Further, separate high-potential voltage lines can be disposed to be shared by the sub-pixels SP arranged in the column direction (Y-axis direction) direction and can deliver the high-potential voltage individually to the plurality of sub-pixels SP. The high-potential voltage line VL1 can be referred to as a first power line.

A low-potential voltage pad VP2 connected to the low-potential voltage line VL2 can be disposed in the second pad area PA2.

The low-potential voltage line VL2 can extend in the column direction (Y-axis direction) and can be disposed on each of left and right sides of the gate driver GD and on each of left and right sides of the high-potential voltage line VL1. The low-potential voltage line VL2 extending in the column direction (Y-axis direction) can receive a low-potential voltage from the low-potential voltage pad VP2 disposed in the second pad area PA2 and can provide the low-potential voltage to the plurality of sub-pixels SP. It is illustrated that the number of the low-potential voltage pads VP2 corresponds to the number of the low-potential voltage lines VL2. However, the present disclosure is not limited thereto. One low-potential voltage pad VP2 can be disposed every at least two low-potential voltage lines VL2.

A plurality of low-potential voltage lines VL2 extending in the column direction (Y-axis direction) can be connected to the auxiliary low-potential voltage line AVL2 extending in the row direction (X-axis direction) and then can be connected to the low-potential voltage pad VP2, which can reduce or prevent a voltage drop. In FIG. 2, it is shown that the auxiliary low-potential voltage line AVL2 is disposed at only one side of the substrate 110. However, the present disclosure is not limited thereto and the auxiliary low-potential voltage line AVL2 can be disposed at least one side of the substrate 110.

Further, separate low-potential voltage lines can be disposed to be shared by the sub-pixels SP arranged in the column direction (Y-axis direction) and can individually deliver the low-potential voltage to the plurality of sub-pixels SP.

Additionally, lines for connecting the plurality of low-potential voltage lines VL2 to each other can extend in the row direction (X-axis direction) in each row where the sub-pixels SP are arranged or in each of the plurality of rows in which the sub-pixels SP are arranged. Accordingly, the auxiliary low-potential voltage line AVL2 can prevent a voltage drop of the low-potential voltage line VL2 and provide the low-potential voltage to the plurality of sub-pixels SP. The low-potential voltage line VL2 can be referred to as a second power line.

A reference voltage line VL3 can extend in the column direction (Y-axis direction) and can be disposed in each unit pixel. For example, the reference voltage line VL3 can be disposed between the second sub-pixel SP2 and the third sub-pixel SP3. The reference voltage line VL3 can be connected to the reference voltage pad VP3 disposed in the first pad area PA1. The reference voltage can be provided from the reference voltage pad VP3 to a plurality of reference voltage lines VL3. The reference voltage line VL3 extending in the column direction (Y-axis direction) can be connected to an auxiliary reference voltage line AVL3 extending in the row direction (X-axis direction) and then can be connected to the reference voltage pad VP3. The reference voltage line VL3 can be referred to as a third power line. Depending on a configuration of the pixel circuit, the reference voltage line VL3 can be omitted.

In the display panel PN included in the display device 100 according to one embodiment of the present disclosure, an edge of the substrate 110 can be removed in a grinding manner to reduce a bezel. The bezel can refer to an edge area of the substrate 110 where the sub-pixel SP is not disposed. During the grinding process, a portion of each of the pad and the line disposed on the edge of the substrate 110 can be removed, and a size of the substrate 110 can be reduced, so that the display panel PN can have a size equal to a size of a final substrate 110F (e.g., see the dotted line in FIG. 2).

Specifically, a significant portion of the pad disposed in each of the first pad area PA1 and the second pad area PA2 can be removed and thus is absent from the final substrate 110F, such that only a very small amount of the pad can remain in the final substrate. Accordingly, the display device 100 according to one embodiment of the present disclosure can have a zero bezel or a near zero bezel.

Hereinafter, a light-emitting element included in the display device 100 according to one embodiment of the present disclosure will be described.

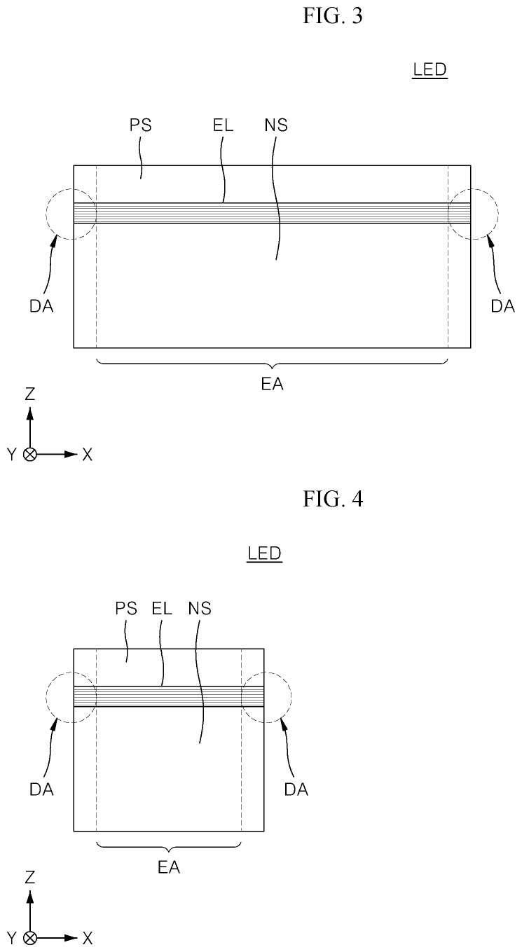

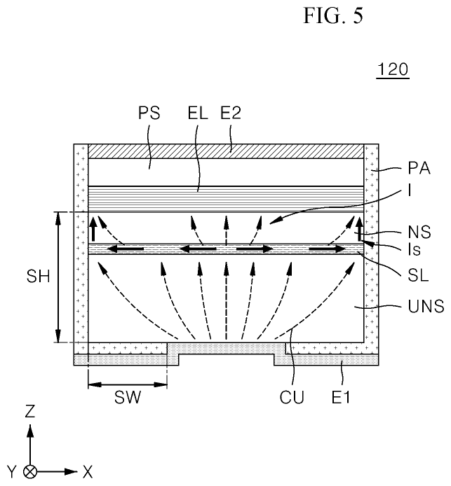

FIG. 3 and FIG. 4 are schematic cross-sectional views of a light-emitting element according to one embodiment of the present disclosure.

FIG. 3 shows a semiconductor structure LED before having a shape of a light-emitting element to be mounted on a display panel. The semiconductor structure LED can have a predefined size and can have a structure in which semiconductor layers are stacked. A size of a side of the semiconductor structure LED on a X-Y plane is greater than or equal to 100 μm. An area size thereof on a Z-X plane is smaller than an area size on the X-Y plane of the semiconductor structure LED.

The semiconductor structure LED can be formed by sequentially growing a first semiconductor layer NS, a light-emitting layer EL, and a second semiconductor layer PS on a wafer to form a stack and then etching a side surface of the stack to form the semiconductor structure LED. In the process of etching the side surface of the stack for forming the semiconductor structure LED, a side surface of the resulting semiconductor structure LED can be damaged due to etching gas and plasma. In particular, a damaged area DA occurs on a side surface of the light-emitting layer EL that emits light. In this situation, abnormal recombination of holes and electrons that does not lead to light-emission occurs in the damaged area, thereby reducing light-emitting efficiency. Accordingly, light emission occurs in an area other than the damaged area DA of the side surface of the light-emitting layer EL. The area in which the light-emission occurs can be referred to as a light-emitting area EA. However, in the semiconductor structure LED in FIG. 3, the area size thereof on the Z-X plane is smaller than area size on the X-Y plane of the semiconductor structure LED. Thus, an effect of the damaged area DA during the light-emission is relatively smaller.

However, referring to FIG. 4, a size of a side of the semiconductor structure LED on a X-Y plane is smaller than or equal to 50 μm. An area size thereof on the Z-X plane is larger than the area size on the X-Y plane of the semiconductor structure LED.

The semiconductor structure LED of FIG. 4 has the same structure as that of the semiconductor structure LED of FIG. 3, whereas the size of the side of the semiconductor structure LED on the X-Y plane in FIG. 3 is different from the size of the side of the semiconductor structure LED on the X-Y plane in FIG. 4. In the process of etching the side surface of the semiconductor structure LED, the damaged area DA can occur on the side surface of the light-emitting layer EL. The area other than the damaged area DA amounts to the light-emitting area EA. However, in the semiconductor structure LED as shown in FIG. 4 in which the area size thereof on the Z-X plane is larger than the area size on the X-Y plane of the semiconductor structure LED, the effect of the damaged area DA during the light-emission is relatively larger. Therefore, when the size of the semiconductor structure LED is 50 μm or smaller, additional structural supplementation is required to increase the light-emitting efficiency of the semiconductor structure LED.

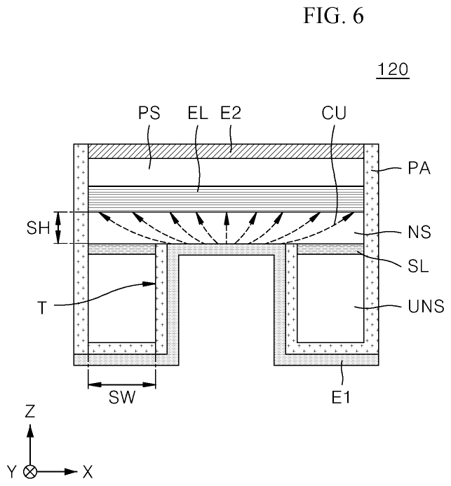

FIG. 5 is a cross-sectional view of a light-emitting element implemented using the semiconductor structure as shown in FIG. 4.

With reference to FIG. 5, the semiconductor structure LED of FIG. 4 will be described in detail.

Referring to FIG. 5, a light-emitting element 120 includes a semiconductor structure composed of a undoped semiconductor layer UNS, a superlattice layer SL, the first semiconductor layer NS, the light-emitting layer EL, and the second semiconductor layer PS, a first electrode E1, a second electrode E2, and a protective layer PA.

The undoped semiconductor layer UNS can include an undoped semiconductor material. For example, the semiconductor material can be a material such as gallium nitride (GaN), indium aluminum phosphide (InAlP), gallium arsenide (GaAs), and the like.

The superlattice layer SL is a layer that prevents defects or dislocation that occurs during thin-film growth of a semiconductor layer from a wafer. When the light-emitting element 120 does not have the superlattice layer SL, internal quantum efficiency of the light-emitting element 120 is low, thus making it difficult to use the light-emitting element as a light source. Therefore, for improved light-emitting efficiency, the light-emitting element 120 includes the superlattice layer SL. For example, the superlattice layer SL can have a multilayer structure in which at least two of an indium gallium nitride (InGaN) layer, a gallium nitride (GaN) layer, and an aluminum gallium nitride (AlGaN) layer are alternately stacked on top of each other.

The first semiconductor layer NS can be disposed on the superlattice layer SL, and can include a semiconductor material containing first conductivity-type impurities. For example, the first conductivity-type impurities can include N-type impurities. The semiconductor material can be a material such as gallium nitride (GaN), indium aluminum phosphide (InAlP), gallium arsenide (GaAs), etc., and the N-type impurities can include silicon (Si), germanium (Ge), tin (Sn), etc. However, the present disclosure is not limited thereto.

The light-emitting layer EL is disposed on the first semiconductor layer NS. The light-emitting layer EL is a layer for emitting light based on combination of holes and electrons, and has a multi-quantum well (MQW) structure having a well layer and a barrier layer having a higher band gap than that of the well layer. For example, the light-emitting layer EL can be composed of an indium gallium nitride (InGaN) layer as the well layer and an aluminum gallium nitride (AlGaN) layer as the barrier layer.

The second semiconductor layer PS is disposed on the light-emitting layer EL. The second semiconductor layer PS can include a semiconductor material containing second conductivity-type impurities. For example, the second conductivity-type impurities can include P-type impurities. The semiconductor material can be a material such as gallium nitride (GaN), indium aluminum phosphide (InAlP), gallium arsenide (GaAs), etc., and the P-type impurities can include magnesium (Mg), zinc (Zn), beryllium (Be), etc. However, the present disclosure is not limited thereto.

In another example, in the light-emitting element according to one embodiment of the present disclosure, the first semiconductor layer NS and the second semiconductor layer PS can be made of the semiconductor material containing the P-type impurities and the semiconductor material containing the N-type impurities, respectively.

The second electrode E2 is disposed on the second semiconductor layer PS. The second electrode E2 can be made of at least one of metal materials such as Au, W, Pt, Si, Ir, Ag, (Cu), (Ni), (Ti), (Cr), or alloys thereof, or can be made of a transparent conductive material such as indium tin oxide (ITO) or indium zinc oxide (IZO).

A protective layer PA is disposed on a remaining portion of a lower surface of the undoped semiconductor layer UNS except for a portion of the lower surface of the undoped semiconductor layer UNS facing the superlattice layer SL in a X-Y plane, and on a side surface of each of the undoped semiconductor layer UNS, the superlattice layer SL, the first semiconductor layer NS, the light-emitting layer EL, the second semiconductor layer PS, the second electrode E2. The protective layer PA protects the semiconductor structure.

Further, the first electrode E1 is disposed on the portion of the lower surface of the undoped semiconductor layer UNS on which the protective layer PA is not disposed. The first electrode E1 can be disposed on the portion of the lower surface of the undoped semiconductor layer UNS and on a lower surface of the protective layer PA. The first electrode E1 can be made of at least one of metal materials such as Au, W, Pt, Si, Ir, Ag, (Cu), (Ni), (Ti), (Cr), or alloys thereof.

In the light-emitting element 120 having a size of 100 μm or larger, the superlattice layer SL included in the light-emitting element 120 according to one embodiment of the present disclosure can allow a current generated from the first electrode E1 to more easily flow from the superlattice layer SL to the side surface of the light-emitting element 120, thereby improving the light-emitting efficiency. For example, the superlattice layer SL can help uniformly spread out the current and improve luminance when the light-emitting element 120 is a certain size or larger (e.g., 100 μm or more).

However, in the light-emitting element 120 having a size of 50 μm or smaller, a speed at which the current Is leaks through the superlattice layer SL to the side surface of the light-emitting element 120 is higher than a speed at which the supplied current CU passes through the light-emitting layer EL. Thus, an amount of current I flowing into the light-emitting layer EL is reduced. For example, too much current can be routed to the sides and uniform luminance is impaired when the light-emitting element 120 is a certain size or smaller (e.g., 50 μm or less). Therefore, when the size of the light-emitting element 120 is 50 μm or smaller, current injection efficiency can decrease. In this situation, the area size of the light-emitting element 120 on the Z-X plane is larger than the area size on the X-Y plane thereof. Further, a height SH from a contact surface between the undoped semiconductor layer UNS and the first electrode E1 to an upper surface of the first semiconductor layer NS is greater than a distance SW from the side surface of the undoped semiconductor layer UNS to a boundary between the protective layer PA and the first electrode E1 at the lower surface of the undoped semiconductor layer UNS (e.g., SH>SW).

Hereinafter, the structure of the light-emitting element 120 with increased current injection efficiency will be described.

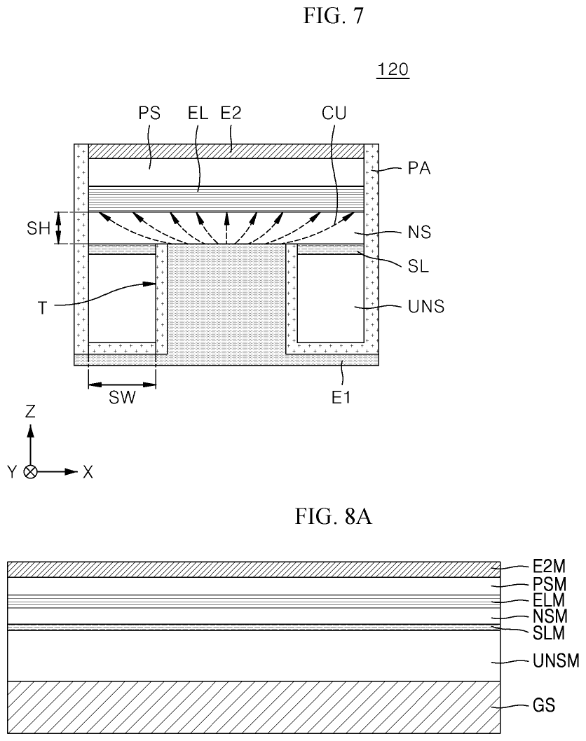

FIG. 6 is a cross-sectional view of a light-emitting element according to another embodiment of the present disclosure. A structure of the light-emitting element of FIG. 6 is identical to the structure of the light-emitting element 120 in FIG. 5 except for the structures and positions of the undoped semiconductor layer UNS, the superlattice layer SL, the protective layer PA, and the first electrode E1. Descriptions of the same components therebetween are omitted or simplified. For example, in FIG. 6 a center area of the first electrode E1 is brought closer to the light-emitting layer EL and the protective layer PA is extended through portions of the superlattice layer SL.

Referring to FIG. 6, the light-emitting element 120 includes the semiconductor structure composed of the undoped semiconductor layer UNS, the superlattice layer SL, the first semiconductor layer NS, the light-emitting layer EL, and the second semiconductor layer PS, the first electrode E1, the second electrode E2, and the protective layer PA.

The undoped semiconductor layer UNS and the superlattice layer SL of the semiconductor structure has a recess T (e.g., a depression or hole) defined therein exposing a portion of a lower surface of the first semiconductor layer NS. Specifically, the undoped semiconductor layer UNS has a first inner side surface defining the recess T, and a first outer side surface. The superlattice layer SL has a second inner side surface defining the recess T, and a second outer side surface. The first side surface of the undoped semiconductor layer UNS and the second side surface of the superlattice layer SL are aligned with each other in a line (e.g., an edge of the undoped semiconductor layer UNS and an edge of the superlattice layer SL are flush with each other).

The protective layer PA is disposed on the first inner side surface of the undoped semiconductor layer UNS, the second inner side surface of the superlattice layer SL, a lower surface of the undoped semiconductor layer UNS, and the side surface of the semiconductor structure (e.g., the protective layer PA extends or wraps around the bottom of the undoped semiconductor layer UNS and covers the sides of the recess T).

Then, the first electrode E1 can be disposed on a portion of a lower surface of the first semiconductor layer NS exposed through the recess T of the semiconductor structure, and on a remaining portion of the protective layer PA except for a portion of the protective layer PA disposed on the side surface of the semiconductor structure. For example, the first electrode E1 extends or wraps around the bottom of light-emitting element 120 and into the recess T, in which a center area of the first electrode E1 is brought closer to a center area of the light-emitting layer EL.

The light-emitting element 120 according to another embodiment of the present disclosure has a structure in which a portion of each of the superlattice layer SL and the undoped semiconductor layer UNS is removed to reduce current leaking to the side surface of the light-emitting element 120 through the superlattice layer SL (e.g., there is a hole through the superlattice layer SL and the undoped semiconductor layer UNS). Accordingly, the first electrode E1 directly contacts the first semiconductor layer NS. Further, a height SH from the contact surface between the first semiconductor layer NS and the first electrode E1 to the upper surface of the first semiconductor layer NS is smaller than a distance SW from the first inner side surface of the undoped semiconductor layer UNS to the first outer side surface of the undoped semiconductor layer UNS (e.g., SH<SW).

When the distance SW from the first inner side surface of the undoped semiconductor layer UNS to the first outer side surface thereof is smaller than the height SH from the contact surface between the first semiconductor layer NS and the first electrode E1 to the upper surface of the first semiconductor layer NS (e.g., SH>SW), a distance between a boundary of the first electrode E1 and the side surface of the light-emitting element 120 decreases, such that the amount of current leaking to the side surface of the light-emitting element 120 increases which can impair luminance. Accordingly, the distance SW from the first inner side surface of the undoped semiconductor layer UNS to the first outer side surface thereof is larger than the height SH from the contact surface between the first semiconductor layer NS and the first electrode E1 to the upper surface of the first semiconductor layer NS (e.g., SH<SW), such that the amount of current leaking to the side surface of the light-emitting element 120 can be reduced and luminance can be improved.

In the light-emitting element 120 according to another embodiment of the present disclosure, a portion of the superlattice layer SL on the X-Y plane is removed (e.g., a hole can be formed through a center area of the superlattice layer SL), such that the current CU generated from the first electrode E1 can immediately pass through the first semiconductor layer NS and into the light-emitting layer EL. This can reduce the amount of the current leaking to the side surface of the light-emitting element 120 and thus can prevent a decrease of the current injection efficiency of the light-emitting element 120 from occurring. In this situation, the area size of the light-emitting element 120 on the Z-X plane is larger than the area size on the X-Y plane thereof.

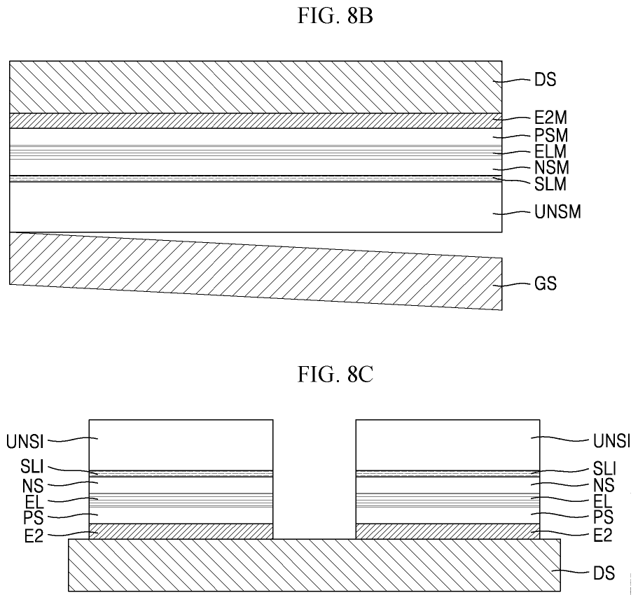

FIG. 7 is a cross-sectional view of a light-emitting element according to still another embodiment of the present disclosure. The remaining components except for the first electrode E1 in the light-emitting element 120 of FIG. 6 can be equally applied to FIG. 7. Descriptions of the same components therebetween are omitted or simplified.

Referring to FIG. 7, the first electrode E1 fills the recess T of the semiconductor structure. For example, in FIG. 7, the hole in the superlattice layer SL and the undoped semiconductor layer UNS can be completely filled by the first electrode E1. In FIG. 6, the first electrode E1 is disposed in the recess T of the semiconductor structure but does not fill the recess T. In FIG. 7, the first electrode E1 can be disposed in the recess T of the semiconductor structure and fills the recess T to allow the lower surface of the light-emitting element 120 to be flat.

Due to the configuration of the first electrode E1, the light-emitting element 120 can have a completely flat bottom surface. Thus, the light-emitting element 120 can be more easily mounted on a substrate, and the first electrode E1 can be easily connected to the substrate, which improves manufacturing yields and reduces defects. A detailed description thereof will be made later.

The light-emitting element 120 according to still another embodiment of the present disclosure can have the recess T formed by removing a portion of each of the superlattice layer SL and the undoped semiconductor layer UNS, thereby reducing the amount of the current leaking to the side surface of the light-emitting element 120 through the superlattice layer SL. The undoped semiconductor layer UNS includes the first inner side surface defining the recess T and the first outer side surface. The superlattice layer SL includes the second inner side surface defining the recess T and the second outer side surface.

Accordingly, the first electrode E1 can directly contact the first semiconductor layer NS. Further, the height SH from the contact surface between the first semiconductor layer NS and the first electrode E1 to the upper surface of the first semiconductor layer NS is smaller than the distance SW from the first inner side surface of the undoped semiconductor layer UNS to the first outer side surface thereof (e.g., SH<SW).

When the distance SW from the first inner side surface of the undoped semiconductor layer UNS to the first outer side surface thereof is smaller than the height SH from the contact surface between the first semiconductor layer NS and the first electrode E1 to the upper surface of the first semiconductor layer NS (e.g., SH>SW), a distance between a boundary of the first electrode E1 and the side surface of the light-emitting element 120 decreases, such that the amount of current leaking to the side surface of the light-emitting element 120 increases and luminance is impaired. Accordingly, the distance SW from the first inner side surface of the undoped semiconductor layer UNS to the first outer side surface thereof is larger than the height SH from the contact surface between the first semiconductor layer NS and the first electrode E1 to the upper surface of the first semiconductor layer NS (e.g., SH<SW), such that the amount of current leaking to the side surface of the light-emitting element 120 can be reduced and luminance can be increased.

In the light-emitting element 120 according to still another embodiment of the present disclosure, the portion of the superlattice layer SL has been removed on the X-Y plane, such that the current generated from the first electrode E1 can directly pass from the first electrode E1, through the first semiconductor layer NS, and into the light-emitting layer EL. This can reduce the amount of the current leaking to the side surface of the light-emitting element 120 and thus can prevent a decrease of the current injection efficiency of the light-emitting element 120 from occurring.

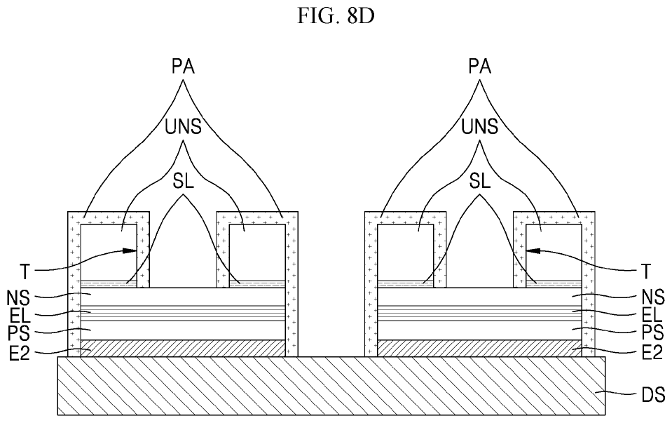

FIG. 8A to FIG. 8E are diagrams of a method for manufacturing a light-emitting element according to one embodiment of the present disclosure. A method for manufacturing the light-emitting element 120 as shown in FIG. 6 is described.

Referring to FIG. 8A, an undoped semiconductor material layer UNSM, a superlattice material layer SLM, a first semiconductor material layer NSM, a light-emitting material layer ELM, and a second semiconductor material layer PSM are sequentially grown on a growth substrate GS. Then, a second electrode material layer E2M is disposed on the second semiconductor material layer PSM.

As previously described, the superlattice material layer SLM is disposed between the undoped semiconductor material layer UNSM and the first semiconductor material layer NSM, such that during the growth of the thin-film layers constituting the semiconductor structure, the defects and dislocations do not occur.

Referring to FIG. 8B, a dummy substrate DS is attached onto the second electrode material layer E2M, and the growth substrate GS is removed from the undoped semiconductor material layer UNSM. The dummy substrate DS can be a material capable of supporting a semiconductor structure, such as glass, quartz, or sapphire. The dummy substrate DS can be attached onto the second electrode material layer E2M using an insulating material such as silicon oxide (SiO₂) or benzocyclobutene (BCB). Then, the growth substrate GS can be removed from the undoped semiconductor material layer UNSM using a process such as laser lift off (LLO), chemical mechanical planarization (CMP), dry etch, wet etch, etc. However, the present disclosure is not limited thereto.

Referring to FIG. 8C, the undoped semiconductor material layer UNSM, the superlattice material layer SLM, the first semiconductor material layer NSM, the light-emitting material layer ELM, the second semiconductor material layer PSM, and the second electrode material layer E2M are partially etched to form a semiconductor structure of a desired size. A size of a side of the semiconductor structure on the X-Y plane can be 50 μm or smaller.

Each of the semiconductor structures separated and spaced from each other after the etching process can be composed of the second electrode E2, the second semiconductor layer PS, the light-emitting layer EL, the first semiconductor layer NS, the superlattice material layer SLI, and the undoped semiconductor material layer UNSI which are sequentially stacked on the dummy substrate DS.

Referring to FIG. 8D, the recess T is formed in each of the semiconductor structures by partially etching the superlattice material layer SLI and the undoped semiconductor material layer UNSI. For example, a hole can be etched into a center of the LED device, which extends through the superlattice material layer SLI and the undoped semiconductor material layer UNSI. After the etching process, the semiconductor structure includes the superlattice layer SL and the undoped semiconductor layer UNS. In this situation, the undoped semiconductor layer UNS includes the first inner side surface and the first outer side surface, and the superlattice layer SL includes the second inner side surface and the second outer side surface. The first inner side surface and the first outer side surface, and the second inner side surface and the second outer side surface can be respectively aligned with each other in a line (e.g., the two inner edges of the superlattice material layer SLI and the undoped semiconductor material layer UNSI can be flush with each other). A portion of the lower surface of the first semiconductor layer NS is exposed through the recess T of the semiconductor structure. Therefore, the first inner side surface, the second inner side surface, and the portion of the upper surface of the first semiconductor layer NS define the recess T of the semiconductor structure.

Subsequently, the protective layer PA surrounds the semiconductor structure except for the portion of the upper surface of the first semiconductor layer NS defining the recess T. Specifically, the protective layer PA can be disposed on an outer side surface of the semiconductor structure, the upper surface of the undoped semiconductor layer UNS, the first inner side surface, and the second inner side surface. For example, the protective layer PA can be coated on the outer sides, on the top (e.g., which can also be referred to as the bottom of the final LED), and on the inner surface of the hole that extends through the superlattice material layer SLI and the undoped semiconductor material layer UNSI,

The protective layer PA is disposed on the second inner side surface of the superlattice layer SL, so that the superlattice layer SL and the first electrode E1 to be formed later can be spaced apart from each other. Accordingly, the leakage of the current generated from the first electrode E1 to the side surface of the light-emitting element 120 through the superlattice layer SL can be prevented.

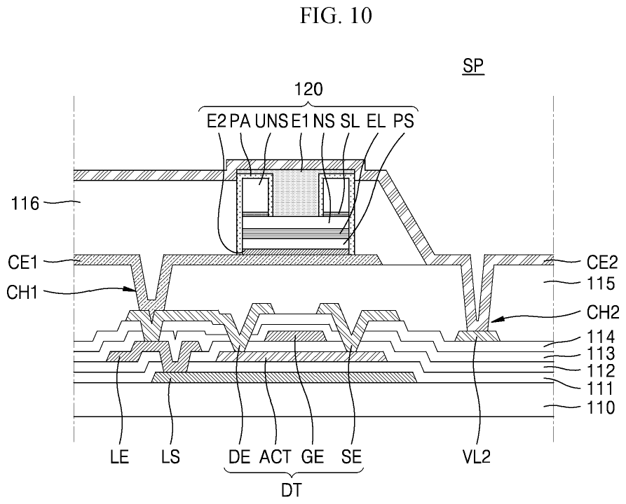

Referring to FIG. 8E, the first electrode E1 is formed on an upper surface of the light-emitting element 120. Specifically, the first electrode E1 is formed on an upper surface of the protective layer PA and an inner side surface of the protective layer PA defining the recess, except for the outer side surface of the protective layer PA formed on the outer side surface of the semiconductor structure. The first electrode E1 directly contacts the first semiconductor layer NS to allow current to pass through the first semiconductor layer NS to the light-emitting layer EL. For example, the first electrode E1 can be coated on top of the protective layer PA and in the hole (e.g., recess T). Also, with reference to FIG. 10, according to another embodiment, the first electrode E1 can be applied so that it completely fills the hole (e.g., recess T).

The upper surface and the lower surface as used herein can be inverted depending on the arrangement of the light-emitting element or the semiconductor structure shown in the drawing.

Next, the dummy substrate DS is removed from the resulting structure. The dummy substrate DS can be removed therefrom in a laser lift off scheme. However, the present disclosure is not limited thereto.

In this way, the dummy substrate DS is removed from the resulting structure to obtain the light-emitting element 120. The dummy substrate DS can be removed therefrom while the light-emitting element 120 is transferred onto a substrate on which the pixel circuit has been formed.

Hereinafter, a structure in which the light-emitting element is disposed on the substrate on which the pixel circuit has been formed will be described.

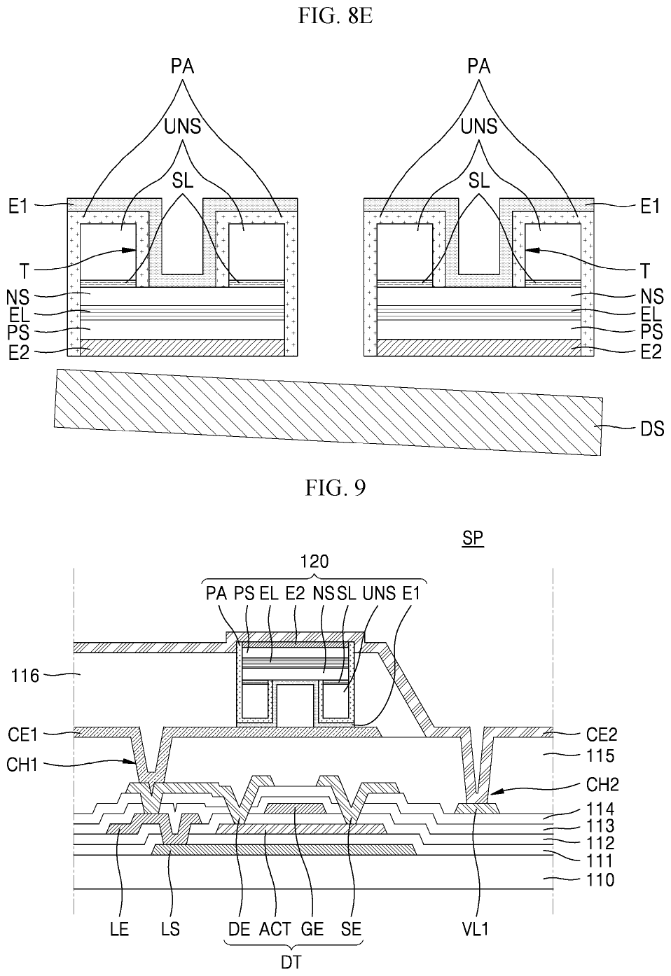

FIG. 9 is a cross-sectional view of a display device according to one embodiment of the present disclosure. FIG. 9 is a cross-sectional view of a partial area of the sub-pixel SP as shown in FIG. 1 and FIG. 2.

Referring to FIG. 9, the display panel PN of the display device 100 according to one embodiment of the present disclosure can include the substrate 110, a buffer layer 111, a gate insulating layer 112, a first interlayer insulating layer 113, a second interlayer insulating layer 114, a first planarization layer 115, a second planarization layer 116, a driving transistor DT, the light-emitting element 120, a first connection electrode CE1, a second connection electrode CE2, a light-blocking layer LS, and an auxiliary electrode LE.

Referring to FIG. 9, the substrate 110 is a component for supporting various components included in the display device 100 and can be made of an insulating material. For example, the substrate 110 can be made of glass or resin. Further, the substrate 110 can be made of polymers or plastic, and can be made of a material with flexibility.

The light-blocking layer LS is disposed on the substrate 110. The light-blocking layer LS prevents light incident from a position under the substrate 110 from invading the active layer ACT of the driving transistor DT, which will be described later. the light-blocking layer LS can prevent the light from being incident to the active layer ACT of the driving transistor DT, thereby minimizing leakage current. Also, the center of the light-emitting element 120 can be aligned over a center of the driving transistor DT, but embodiments are not limited thereto.

The buffer layer 111 is disposed on the substrate 110 and the light-blocking layer LS. The buffer layer 111 can reduce the permeation of moisture or impurities through the substrate 110. The buffer layer 111 can be composed of, for example, a single layer or a multi-layer made of silicon oxide (SiOx) or silicon nitride (SiNx). However, the present disclosure is not limited thereto. However, the buffer layer 111 can be omitted depending on a type of the substrate 110 or a type of the transistor. However, the present disclosure is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT can be made of a semiconductor material such as oxide semiconductor, amorphous silicon, or polysilicon. However, the present disclosure is not limited thereto.

The gate insulating layer 112 is disposed on the active layer ACT. The gate insulating layer 112 is an insulating layer for insulating the active layer ACT and the gate electrode GE from each other, and can be composed of a single layer or a multi-layer made of silicon oxide (SiOx) or silicon nitride (SiNx). However, the present disclosure is not limited thereto.

The gate electrode GE is disposed on the gate insulating layer 112. The gate electrode GE can be electrically connected to the source electrode SE of the driving transistor DT. The gate electrode GE can be made of a conductive material such as copper (Cu), aluminum (Al), molybdenum (Mo), nickel (Ni), titanium (Ti), chromium (Cr), or an alloy thereof. However, the present disclosure is not limited thereto. Also, a center of the recess T can be aligned over a center of the gate electrode GE, but embodiments are not limited thereto.

The first interlayer insulating layer 113 and the second interlayer insulating layer 114 are disposed on the gate electrode GE. The first interlayer insulating layer 113 and the second interlayer insulating layer 114 have contact-holes defined therein for respectively connecting the source electrode SE and the drain electrode DE to the active layer ACT. Each of the first interlayer insulating layer 113 and the second interlayer insulating layer 114 acts as an insulating layer for protecting components under the first interlayer insulating layer 113 and the second interlayer insulating layer 114, and can be composed of a single layer or double layers made of silicon oxide (SiOx) or silicon nitride (SiNx). However, the present disclosure is not limited thereto.

The source electrode SE and the drain electrode DE electrically connected to the active layer ACT are disposed on the second interlayer insulating layer 114. Each of the source electrode SE and the drain electrode DE can be made of a conductive material such as copper (Cu), aluminum (Al), molybdenum (Mo), nickel (Ni), titanium (Ti), chromium (Cr), or an alloy thereof. However, the present disclosure is not limited thereto.

In one example, the present disclosure describes an example in which the first interlayer insulating layer 113 and the second interlayer insulating layer 114, that is, a plurality of insulating layers are disposed between the gate electrode GE and the source electrode SE, and the drain electrode DE. However, the present disclosure is not limited thereto. Only one insulating layer can be disposed between the gate electrode GE and the source electrode SE, and the drain electrode DE. However, when, as shown in the drawing, the plurality of insulating layers such as the first interlayer insulating layer 113 and the second interlayer insulating layer 114 are disposed between the gate electrode GE and the source electrode SE, and the drain electrode DE, an electrode can be additionally formed between the first interlayer insulating layer 113 and the second interlayer insulating layer 114. The additionally formed electrode and another component disposed under the first interlayer insulating layer 113 or on top of the second interlayer insulating layer 114 can constitute a capacitor.

The auxiliary electrode LE is disposed on the gate insulating layer 112. The auxiliary electrode LE acts as an electrode that electrically connects the light-blocking layer LS disposed under the buffer layer 111 to one of the source electrode SE and the drain electrode DE disposed on the second interlayer insulating layer 114. For example, since the light-blocking layer LS is electrically connected to either the source electrode SE or the drain electrode DE via the auxiliary electrode LE and does not operate as a floating gate, a change in a threshold voltage of the driving transistor DT otherwise caused by the floating light-blocking layer LS can be minimized or prevented. In the drawing, the light-blocking layer LS is shown as being connected to the drain electrode DE. However, the present disclosure is not limited thereto. The light-blocking layer LS can be connected to the source electrode SE.

The first power line VL1 is disposed on the second interlayer insulating layer 114. The first power line VL1 together with the driving transistor DT can be electrically connected to the light-emitting element 120 such that the light-emitting element 120 emits light. The first power line VL1 can be made of a conductive material such as copper (Cu), aluminum (Al), molybdenum (Mo), nickel (Ni), titanium (Ti), chromium (Cr), or an alloy thereof. However, the present disclosure is not limited thereto.

The first planarization layer 115 is disposed on the driving transistor DT and the first power line VL1. The first planarization layer 115 planarizes a surface of a portion on top of the driving transistor DT disposed on the substrate 110. The first planarization layer 115 can be composed of a single layer or a multi-layer made of, for example, photoresist or acryl-based organic material. However, the present disclosure is not limited thereto.

The first connection electrode CE1 is disposed on the first planarization layer 115. The first connection electrode CE1 acts as an electrode for electrically connecting the light-emitting element 120 and the driving transistor DT to each other. The first connection electrode CE1 can be electrically connected to one of the source electrode SE and the drain electrode DE of the driving transistor DT via a first contact-hole CH1 formed in the first planarization layer 115. The first connection electrode CE1 is formed in an area to which the light-emitting element 120 is to be transferred such that the first connection electrode CE1 is electrically connected to the first electrode E1 of the light-emitting element 120. Accordingly, the first connection electrode CE1 can electrically connect the source electrode SE or the drain electrode DE of the driving transistor DT to the first electrode E1 of the light-emitting element 120.

The light-emitting element 120 is disposed on the first connection electrode CE1. The light-emitting element 120 emits light based on current applied thereto. The light-emitting element 120 can emit red light, green light, blue light, or the like. Combination of the red light, green light, blue light can result in various colors including white.

In the display device according to one embodiment of the present disclosure, the first electrode E1 of the light-emitting element 120 is electrically connected to the first connection electrode CE1. The first electrode E1 and the first connection electrode CE1 can be in direct contact with each other.

In the display device according to one embodiment of the present disclosure, an example in which the light-emitting element 120 is embodied as the light-emitting element of FIG. 6 is illustrated. However, the present disclosure is not limited thereto. the light-emitting element 120 can be embodied as the light-emitting element of FIG. 7.

In one example, the light-emitting element 120 can have a cylindrical shape or can have a reverse tapered shape in a cross-sectional view thereof. When the light-emitting element 120 has the reverse tapered shape in the cross-sectional view thereof, a width thereof can increase as the light-emitting element 120 extends upwardly from a bottom to a top of the light-emitting element 120. The first semiconductor layer NS can have an upper surface having a larger area than that of a lower surface thereof. The second semiconductor layer PS can also have an upper surface having a larger area than that of a lower surface thereof.

Next, the second planarization layer 116 is disposed on the first planarization layer 115, the first connection electrode CE1, and the light-emitting element 120. The second planarization layer 116 can planarize a surface of a portion on top of the light-emitting element 120 disposed on the substrate 110, and can fix the light-emitting element 120 onto the substrate 110 (e.g., the second planarization layer 116 can surround the light-emitting element 120 and hold it in place). The second planarization layer 116 can be composed of a single layer or a multi-layer, and can be made of, for example, photoresist or acryl-based organic material. However, the present disclosure is not limited thereto.

The second planarization layer 116 can be partially formed on an area of the substrate 110 overlapping at least the light-emitting element 120 and the first connection electrode CE1. The second planarization layer 116 can be absent in an area overlapping the first power line VL1 so that a second contact-hole CH2 formed in the first planarization layer 115 is exposed to the outside.

In one example, the second planarization layer 116 can be formed to have a height sized such that a top surface of the second planarization layer 116 is positioned at a higher level than that of the light-emitting layer EL of the light-emitting element 120. A thickness of the second planarization layer 116 can be greater than a sum of a thickness of the first semiconductor layer NS and a thickness of the light-emitting layer EL of the light-emitting element 120. Further, the thickness of the second planarization layer 116 can be smaller than a total thickness of the light-emitting element 120. For example, the upper surface of the second planarization layer 116 can be positioned at a level higher than that of the light-emitting layer EL of the light-emitting element 120 and can be positioned at the same level as or lower than a level of the upper surface of the second semiconductor layer PS. During manufacturing of the display device 100, only the second electrode E2 may not be covered with the second planarization layer 116 so that the second connection electrode CE2 is electrically connected to the second electrode E2. For example, the upper surface of the second planarization layer 116 can be positioned at a specific height so that the second electrode E2 sticks out (e.g., which can help with electrically connecting the second electrode E2 with the second connection electrode CE2), but embodiments are not limited thereto.

The second connection electrode CE2 is disposed on the second planarization layer 116 and the light-emitting element 120. The second connection electrode CE2 acts as an electrode for electrically connecting the light-emitting element 120 and the first power line VL1 to each other. The second connection electrode CE2 can be electrically connected to the first power line VL1 via the second contact-hole CH2 not covered with the second planarization layer 116. The second connection electrode CE2 can be disposed to cover the second electrode E2 of the light-emitting element 120 not covered with the second planarization layer 116 and can be electrically connected to the second electrode E2.

FIG. 10 is a cross-sectional view of a display device according to another embodiment of the present disclosure. The display device of FIG. 10 has a structure identical to the structure of the display device of FIG. 9 except for the light-emitting element 120 and the first power line VL1. For example, in FIG. 10, the light-emitting element 120 is flipped and the recess T is completely filled with the first electrode E1. Descriptions of the same components therebetween are omitted or simplified.

Referring to FIG. 10, the display panel PN of the display device 100 according to one embodiment of the present disclosure includes the substrate 110, the buffer layer 111, the gate insulating layer 112, the first interlayer insulating layer 113, the second interlayer insulating layer 114, the first planarization layer 115, the second planarization layer 116, the driving transistor DT, the light-emitting element 120, the first connection electrode CE1, the second connection electrode CE2, the light-blocking layer LS, and the auxiliary electrode LE.

Referring to FIG. 10, the light-blocking layer LS, the driving transistor DT, a conductive layer of the auxiliary electrode LE, and a driving element are disposed on the substrate 110. The buffer layer 111, the gate insulating layer 112, the first interlayer insulating layer 113 and the second interlayer insulating layer 114 are disposed between the conductive layer and the driving element. As mentioned above, both the first interlayer insulating layer 113 and the second interlayer insulating layer 114 can be disposed, or either one of the two interlayer insulating layers can be disposed.

The source electrode SE and the drain electrode DE electrically connected to active layer ACT are disposed on the second interlayer insulating layer 114. The second power line VL2 is disposed in the same layer as a layer in which the source electrode SE and the drain electrode DE are disposed. The second power line VL2 together with the driving transistor DT are electrically connected to the light-emitting element 120 such that the light-emitting element 120 emits light. The second power line VL2 can be made of a conductive material such as copper (Cu), aluminum (Al), molybdenum (Mo), nickel (Ni), titanium (Ti), chromium (Cr), or an alloy thereof. However, the present disclosure is not limited thereto.

The first planarization layer 115 is disposed on the driving transistor DT and the second power line VL2. The first connection electrode CE1 is disposed on the first planarization layer 115. The first connection electrode CE1 acts as an electrode for electrically connecting the light-emitting element 120 and the driving transistor DT to each other. The first connection electrode CE1 can be electrically connected to one of the source electrode SE and the drain electrode DE of the driving transistor DT via the first contact-hole CH1 formed in the first planarization layer 115. The first connection electrode CE1 is formed in an area to which the light-emitting element 120 is to be transferred such that the first connection electrode CE1 is electrically connected to the second electrode E2 of the light-emitting element 120. Accordingly, the first connection electrode CE1 can electrically connect the source electrode SE or the drain electrode DE of the driving transistor DT to the second electrode E2 of the light-emitting element 120.

The light-emitting element 120 is disposed on the first connection electrode CE1. The light-emitting element 120 emits light based on current applied thereto. The light-emitting element 120 can emit red light, green light, blue light, or the like. Combination of the red light, green light, blue light can result in various colors including white.

In the display device according to another embodiment of the present disclosure, the second electrode E2 of the light-emitting element 120 is electrically connected to the first connection electrode CE1. The second electrode E2 and the first connection electrode CE1 can be in direct contact with each other.

In the display device according to another embodiment of the present disclosure, an example in which the light-emitting element 120 is embodied as the light-emitting element of FIG. 7 in which the first electrode E1 fills the recess is illustrated. However, the present disclosure is not limited thereto, and the light-emitting element 120 can be embodied as the light-emitting element of FIG. 6.

In one example, the light-emitting element 120 can have a cylindrical shape or can have a tapered shape in a cross-sectional view thereof. When the light-emitting element 120 has the tapered shape in the cross-sectional view thereof, a width thereof can decrease as the light-emitting element 120 extends upwardly from a bottom to a top of the light-emitting element 120. The first semiconductor layer NS can have an upper surface having a smaller area than that of a lower surface thereof. The second semiconductor layer PS can also have an upper surface having a smaller area than that of a lower surface thereof.

Next, the second planarization layer 116 is disposed on the first planarization layer 115, the first connection electrode CE1, and the light-emitting element 120. The second planarization layer 116 can be partially formed on an area of the substrate 110 overlapping at least the light-emitting element 120 and the first connection electrode CE1. The second planarization layer 116 can be absent in an area overlapping the second power line VL2 so that the second contact-hole CH2 formed in the first planarization layer 115 is exposed to the outside.

In one example, a thickness of the second planarization layer 116 can be greater than a sum of a thickness of the second semiconductor layer PS and a thickness of the light-emitting layer EL of the light-emitting element 120. Further, the thickness of the second planarization layer 116 can be smaller than a total thickness of the light-emitting element 120. For example, the upper surface of the second planarization layer 116 can be positioned at a level higher than that of the light-emitting layer EL of the light-emitting element 120 and can be positioned at the same level as or lower than a level of the upper surface of the first semiconductor layer NS or the undoped semiconductor layer UNS. During manufacturing of the display device 100, only the first electrode E1 may not be covered with the second planarization layer 116 so that the second connection electrode CE2 is electrically connected to the first electrode E1. For example, the first electrode E1 can stick out higher than the upper surface of second planarization layer 116.

The second connection electrode CE2 is disposed on the second planarization layer 116 and the light-emitting element 120. The second connection electrode CE2 acts as an electrode for electrically connecting the light-emitting element 120 and the second power line VL2 to each other. The second connection electrode CE2 can be electrically connected to the second power line VL2 via the second contact-hole CH2 not covered with the second planarization layer 116. The second connection electrode CE2 can be disposed to cover the first electrode E1 of the light-emitting element 120 not covered with the second planarization layer 116, and thus can be electrically connected to the first electrode E1.

A light-emitting device according to embodiments of the present disclosure can be described as follows.

A light-emitting device includes a semiconductor structure including a undoped semiconductor layer, a superlattice layer, a first semiconductor layer, a light-emitting layer, and a second semiconductor layer; a protective layer disposed on a side surface of the semiconductor structure; a first electrode electrically connected to the first semiconductor layer; and a second electrode electrically connected to the second semiconductor layer, in which a recess is formed in the undoped semiconductor layer and the superlattice layer to expose a portion of a surface of the first semiconductor layer.

In some implementations of the light-emitting device, the undoped semiconductor layer is a semiconductor layer which is not doped with impurities, the first semiconductor layer is a semiconductor layer doped with N-type impurities, and the second semiconductor layer is a semiconductor layer doped with P-type impurities.

In some implementations of the light-emitting device, a height from the superlattice layer to the light-emitting layer is smaller than a width of the undoped semiconductor layer.

In some implementations of the light-emitting device, the protective layer is further disposed on an inner side surface of the recess.

In some implementations of the light-emitting device, the first electrode is disposed on the protective layer in the recess, and is disposed on the portion of the surface of the first semiconductor layer exposed through the recess.

In some implementations of the light-emitting device, the first electrode fills the recess.

In some implementations of the light-emitting device, the protective layer is further disposed on a bottom surface of the undoped semiconductor layer.

In some implementations of the light-emitting device, the first electrode is disposed on a portion of the protective layer disposed on the bottom surface of the undoped semiconductor layer.

A display device according to embodiments of the present disclosure can be described as follows.

A display device includes a substrate; a first connection electrode and a second connection electrode disposed on the substrate; and a light-emitting element including a first electrode connected to the first connection electrode and a second electrode connected to the second connection electrode, in which the light-emitting element includes: a undoped semiconductor layer including a first inner side surface and a first outer side surface; a superlattice layer disposed on the undoped semiconductor layer and including a second inner side surface and a second outer side surface; a first semiconductor layer disposed on the superlattice layer; a light-emitting layer disposed on the first semiconductor layer; and a second semiconductor layer disposed on the light-emitting layer.

In some implementations of the display device, the light-emitting element further includes a protective layer, in which the protective layer is disposed on at least the first inner side surface of the undoped semiconductor layer, the second inner side surface of the superlattice layer outer side surfaces of the light-emitting layer, and on a bottom surface of the undoped semiconductor layer.

In some implementations of the display device, the first semiconductor layer is in contact with the first electrode, and the second semiconductor layer is in contact with the second electrode.

In some implementations of the display device, the display device further comprises a driving transistor disposed on the substrate, and a first planarization layer disposed on the driving transistor.

In some implementations of the display device, the display device further comprises a second planarization layer disposed between the first connection electrode and the second connection electrode and surrounding an outer side surface of the light-emitting element.

In some implementations of the display device, the driving transistor includes an oxide semiconductor layer or a polysilicon semiconductor layer.

In some implementations of the display device, the light-emitting element is a micro-LED.

In some implementations of the display device, each of the first electrode and the second electrode is embodied as a single layer or as multilayers made of at least one of ITO, (Mo), (Al), (Cu), (Ni), (Ti), Au, W, Pt, Ir, or Cr or an alloy thereof.

In some implementations of the display device, the display device further comprises: a high-potential voltage line disposed on the substrate and electrically connected to the first electrode; and a low-potential voltage line disposed on the substrate and electrically connected to the second electrode.

In some implementations of the display device, the high-potential voltage lines and the low-potential voltage lines intersect each other to form a mesh structure.

In some implementations of the display device, a height from the superlattice layer to the light-emitting layer is smaller than a width of the undoped semiconductor layer.

In some implementations of the display device, a recess is formed in the undoped semiconductor layer and the superlattice layer to expose a portion of a surface of the first semiconductor layer.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A light-emitting device comprising:
a semiconductor structure including a undoped semiconductor layer, a superlattice layer, a first semiconductor layer, a light-emitting layer, and a second semiconductor layer;
a protective layer disposed on a side surface of the semiconductor structure;
a first electrode electrically connected to the first semiconductor layer; and
a second electrode electrically connected to the second semiconductor layer, wherein a recess is formed in the undoped semiconductor layer and the superlattice layer, and the recess exposes a portion of a surface of the first semiconductor layer.

2. The light-emitting device of claim 1, wherein the undoped semiconductor layer is not doped with impurities, the first semiconductor layer is doped with N-type impurities, and the second semiconductor layer is doped with P-type impurities.

3. The light-emitting device of claim 1, wherein a height from the superlattice layer to the light-emitting layer is smaller than a width of the undoped semiconductor layer.

4. The light-emitting device of claim 1, wherein a portion of the protective layer is disposed on an inner side surface of the recess.

5. The light-emitting device of claim 4, wherein the first electrode is disposed on the portion of the protective layer in the recess and on the portion of the surface of the first semiconductor layer exposed by the recess.

6. The light-emitting device of claim 5, wherein the first electrode fills the recess.

7. The light-emitting device of claim 1, wherein a lower portion of the protective layer is further disposed on a bottom surface of the undoped semiconductor layer.

8. The light-emitting device of claim 7, wherein the first electrode is disposed on the lower portion of the protective layer.

9. A display device comprising:
a first connection electrode and a second connection electrode disposed on a substrate; and
a light-emitting element including a first electrode connected to the first connection electrode and a second electrode connected to the second connection electrode, wherein the light-emitting element includes:
a undoped semiconductor layer including a first inner side surface and a first outer side surface;
a superlattice layer disposed on the undoped semiconductor layer, the superlattice layer including a second inner side surface and a second outer side surface;
a first semiconductor layer disposed on the superlattice layer;
a light-emitting layer disposed on the first semiconductor layer; and
a second semiconductor layer disposed on the light-emitting layer.

10. The display device of claim 9, wherein the first inner side surface of the undoped semiconductor layer is flush with the second inner side surface of the superlattice layer.

11. The display device of claim 9, wherein the light-emitting element further includes a protective layer,
wherein the protective layer is disposed on at least the first inner side surface of the undoped semiconductor layer, the second inner side surface of the superlattice layer, outer side surfaces of the light-emitting element, and on a bottom surface of the undoped semiconductor layer.

12. The display device of claim 9, wherein the first semiconductor layer is in direct contact with the first electrode, and the second semiconductor layer is in direct contact with the second electrode.

13. The display device of claim 9, further comprising:
a driving transistor disposed on the substrate; and
a first planarization layer disposed on the driving transistor.

14. The display device of claim 13, further comprising:
a second planarization layer disposed between the first connection electrode and the second connection electrode, the second planarization layer surrounding an outer side surface of the light-emitting element.

15. The display device of claim 13, wherein the driving transistor includes an oxide semiconductor layer or a polysilicon semiconductor layer.

16. The display device of claim 9, wherein the light-emitting element is a micro-LED having a width that is less than or equal to about 100 μm.

17. The display device of claim 9, wherein each of the first electrode and the second electrode includes one or more layers made of at least one of ITO, Mo, Al, Cu, Ni, Ti, Au, W, Pt, Ir, or Cr or an alloy thereof.

18. The display device of claim 9, further comprising:
a high-potential voltage line disposed on the substrate and electrically connected to the first electrode; and
a low-potential voltage line disposed on the substrate and electrically connected to the second electrode.

19. The display device of claim 18, wherein the high-potential voltage line and the low-potential voltage line intersect each other to form a mesh structure.

20. The display device of claim 9, wherein a height from the superlattice layer to the light-emitting layer is smaller than a width of the undoped semiconductor layer.

21. The display device of claim 9, wherein a recess is formed in the undoped semiconductor layer and the superlattice layer, and the recess exposes a portion of a surface of the first semiconductor layer.

22. The display device of claim 9, wherein the undoped semiconductor layer, the superlattice layer, the first semiconductor layer, the light-emitting layer, and the second semiconductor layer are stacked sequentially.

23. A light-emitting device comprising:
a first electrode;
a first semiconductor layer;
a protective layer disposed between the first electrode and the first semiconductor layer;
a superlattice layer disposed on the first semiconductor layer;
a light-emitting layer configured to emit light;
a second semiconductor layer disposed between the superlattice layer and the light-emitting layer;
a third semiconductor layer disposed on the light-emitting layer;
a second electrode disposed on the third semiconductor layer; and
a hole extending through the first semiconductor layer and the superlattice layer, wherein a portion of the first electrode is disposed in the hole.

24. The light-emitting device of claim 23, wherein the portion of the first electrode disposed in the hole contacts the second semiconductor layer.

25. The light-emitting device of claim 23, wherein a portion of the protective layer is coated along an inside of the hole.

26. The light-emitting device of claim 25, wherein a portion of the first electrode is coated along the portion of the protective layer that is coated along the inside of the hole.

27. The light-emitting device of claim 26, wherein the first electrode completely fills the hole.

28. The light-emitting device of claim 23, wherein a length from an inner side surface of the hole to an outer side surface of the first semiconductor layer is greater than a thickness of the second semiconductor layer.

29. The light-emitting device of claim 23, wherein the first semiconductor layer is an undoped semiconductor layer, and the second and third semiconductor layers are doped semiconductor layers.
